(19) United States
(12) Patent Application Publication
(10) Pub. No.: US 2012/0002147 A1
(43) Pub. Date: Jan. 5, 2012

(54) METHOD FOR MANUFACTURING LIQUID CRYSTAL DISPLAY DEVICE AND LIQUID CRYSTAL DISPLAY DEVICE MANUFACTURED THEREBY

(76) Inventor: Yoshikazu Umeno, Osaka (JP)

(21) Appl. No.: 13/148,889

(22) PCT Filed: Nov. 16, 2009
(86) PCT No.: PCT/JP2009/006107

§ 371 Date: Aug. 10, 2011

(30) Foreign Application Priority Data
Mar. 23, 2009 (JP) 2009-070528

(51) Int. Cl. G02F 1/1333; H01L 33/08

(52) U.S. Cl. 349/110; 438/30; 257/E33.012

(57) ABSTRACT

A liquid crystal display panel (14) is prepared, which includes a TFT substrate (11) having a glass substrate (21) and a CF substrate (12) provided so as to face the TFT substrate (11) with a liquid crystal layer (13) being interposed therebetween, and which has a bright spot defective portion (18) therein. A recessed portion (2) is formed by grinding a region of the glass substrate (21) corresponding to the bright spot defective portion (18) on a surface of the glass substrate (21), which is opposite to a surface facing the liquid crystal layer (13), with an electrodeposited grinding stone. The recessed portion (2) is etched, and a light-shielding portion (3) made of light-shielding material is formed in the recessed portion (2).

### TECHNICAL FIELD

The present invention relates to a method for manufacturing a liquid crystal display device in which a pair of substrates are stacked with a predetermined clearance being interposed therebetween and a liquid crystal layer is sealed in the clearance between the pair of substrates, and to a liquid crystal display device manufactured by the method.

### BACKGROUND ART

Recently, as display panels for mobile terminals such as mobile phones and portable game machines and for various types of electronic devices such as laptop computers, a thin lightweight liquid crystal display panel has been broadly used because of its advantages that the liquid crystal display panel can be driven at low voltage and power consumption thereof is low.

The liquid crystal display panel generally includes, e.g., a TFT (thin film transistor) substrate on which a plurality of pixel electrodes are arranged in matrix, a CF (color filter) substrate arranged so as to face the TFT substrate and having a common electrode, and a liquid crystal layer provided between the TFT substrate and the CF substrate. After the TFT substrate and the CF substrate are produced, both substrates are bonded together to produce a hollow panel, and liquid crystal material is injected and sealed between the substrates forming the panel, thereby manufacturing the liquid crystal display panel. Then, a product test such as a lighting test is performed for the manufactured liquid crystal display panel.

For example, in the lighting test, test signals are input to all of the pixel electrodes of the TFT substrate and the common electrode of the CF substrate, and all of the pixels are in a light-on state. Then, the liquid crystal display panel is irradiated with light from a backlight from the back of the liquid crystal display panel, and a pixel in which a short circuit is caused due to conductive foreign substances interposed between the pixel electrode and the common electrode, i.e., a pixel having a defect (defective pixel) is detected as a bright spot. In the liquid crystal display panel from which the bright spot is detected, such a bright spot causes a display defect.

As a technique for correcting the display defect, e.g., a tip end portion of a sharpened carbide drill (pen tip to which a diamond head is attached) is pressed against a position optically overlapped with a portion where the bright spot defect is caused, on a surface of a glass substrate forming the TFT substrate to cut the glass substrate, thereby forming a recessed portion. A liquid crystal display device is disclosed, in which light-shielding material is provided in the recessed portion. According to the liquid crystal display device, the bright spot defect can be corrected without the need for a special device and a complex operation and without causing disadvantages such as bubble generation between a polarizing plate and a liquid crystal display panel (see, e.g., Patent Document 1).

### CITATION LIST

### Patent Document

PATENT DOCUMENT 1: Japanese Patent Publication No. 2005-189360

### SUMMARY OF THE INVENTION

### Technical Problem

As described above, progress has been recently made in reduction in thickness of a liquid crystal display panel. In a liquid crystal display device including a medium-to-small size liquid crystal display panel, such as a medium-to-small size liquid crystal television, the thickness of a glass substrate forming, e.g., a TFT substrate of the liquid crystal display panel tends to be reduced to about 200 μm.

A problem has been caused, in which it is difficult to cut the thin glass substrate having the foregoing thickness with the carbide drill described in Patent Document 1. More specifically, when cutting the glass substrate with the carbide drill described in Patent Document 1, a recessed portion having a depth of about 200 μm-300 μm is formed. Thus, the cutting with the carbide drill is effective for a liquid crystal display device which includes a large size liquid crystal display panel, such as a large size liquid crystal television and in which the thickness of a glass substrate forming, e.g., a TFT substrate is about 700 μm. However, when cutting a glass substrate having only a thickness of about 200 μm with the carbide drill to form a recessed portion, the remaining portion of the glass substrate in the recessed portion cannot be ensured or becomes extremely thin. Thus, there is a problem that strength of the glass substrate is significantly reduced, and the glass substrate is easily broken even when small force is applied to the recessed portion.

Since the glass substrate having the small thickness (i.e., having the thickness of about 200 μm) cannot be cut with the carbide drill described in Patent Document 1, there is a problem that the liquid crystal display device including the medium-to-small size liquid crystal display panel from which the defective pixel is detected as the bright spot has to be disposed, thereby reducing a manufacturing yield rate.

The present invention has been made in view of the foregoing. In particular, it is an objective of the present invention to provide a method for manufacturing a liquid crystal display device, by which a liquid crystal display device including a medium-to-small size liquid crystal display panel from which a defective pixel is detected as a bright spot is repaired without being disposed, and therefore a manufacturing yield rate can be improved, and to provide a liquid crystal display device manufactured by the method.

### Solution to the Problem

In order to achieve the foregoing objective, a method for manufacturing a liquid crystal display device includes at least preparing a liquid crystal display panel which includes a first substrate having a glass substrate and a second substrate provided so as to face the first substrate with a liquid crystal layer being interposed therebetween and which has a bright spot defective portion therein; forming a recessed portion by grinding a region of the glass substrate corresponding to the bright spot defective portion on a surface of the glass substrate, which is opposite to a surface facing the liquid crystal layer, with an electrodeposited grinding stone; etching the recessed portion; and forming a light-shielding portion made of light-shielding material in the recessed portion.

According to the foregoing configuration, the recessed portion is formed by the grinding with the electrodeposited grinding stone. Thus, unlike cutting with a carbide drill, the recessed portion having a depth of about 50-100 μm can be formed, and occurrence of chipping at a rim of the recessed portion can be effectively reduced. As a result, even if a recessed portion is formed in a thin glass substrate having a thickness of about 200 μm, sufficient strength of the glass substrate can be ensured. In addition, the configuration is employed, in which the recessed portion is etched. Thus, even if microcracks are caused in the recessed portion due to the grinding with the electrodeposited grinding stone, the microcracks can be sealed. Consequently, the strength of the glass substrate including the recessed portion can be improved. As a result, in a liquid crystal display device including a medium-to-small size liquid crystal display panel from which a defective pixel is detected as a bright spot, the bright spot defect can be corrected. Thus, the liquid crystal display device including the medium-to-small size liquid crystal display panel from which the defective pixel is detected as the bright spot can be repaired without being disposed, thereby improving a manufacturing yield rate of the liquid crystal display device.

In the etching the recessed portion of the method of the present invention, hydrofluoric acid may be used to perform the etching.

According to the foregoing configuration, the microcracks caused in the recessed portion can be effectively sealed by a hardening effect due to erosion of hydrofluoric acid. As a result, the strength of the glass substrate including the recessed portion can be further improved, thereby further improving the manufacturing yield rate of the liquid crystal display device.

In the etching the recessed portion of the method of the present invention, a concentration of the hydrofluoric acid may be 20-30% by mass, and an etching rate may be 2-10 μm/minute.

According to the foregoing configuration, sealing of the microcracks caused in the recessed portion can be ensured by the hardening effect due to erosion of hydrofluoric acid.

In the etching the recessed portion of the method of the present invention, an etching time is 20-90 seconds.

According to the foregoing configuration, the sealing of the microcracks can be further ensured by the hardening effect due to erosion of hydrofluoric acid.

The method of the present invention has an excellent characteristic that the liquid crystal display device including the medium-to-small size liquid crystal display panel from which the defective pixel is detected as the bright spot can be repaired without being disposed, thereby improving the manufacturing yield rate of the liquid crystal display device. Thus, the method of the present invention is preferably used as a method for manufacturing a liquid crystal display device in which the thickness of a glass substrate is 200-700 μm. In addition, the method of the present invention is preferably used as a method for manufacturing a liquid crystal display device, in which a glass substrate is made of a material selected from a group including alkali-free glass, aluminosilicate glass, and aluminoborosilicate glass.

In the forming a recessed portion of the method of the present invention, a portion of the electrodeposited grinding stone, which is to contact the glass substrate is flattened in shape.

According to the foregoing configuration, a bottom surface of the recessed portion is flattened. Thus, when forming the light-shielding portion, the light-shielding material supplied to the recessed portion can be effectively held.

### Advantages of the Invention

According to the present invention, the liquid crystal display device including the medium-to-small size liquid crystal display panel from which the defective pixel is detected as the bright spot can be repaired without being disposed, thereby improving the manufacturing yield rate of the liquid crystal display device.

### BRIEF DESCRIPTION OF THE DRAWINGS

FIG. 1 is a cross-sectional view of a liquid crystal display device of an embodiment of the present invention.

FIG. 2 is a cross-sectional view illustrating a step for manufacturing the liquid crystal display device of the embodiment of the present invention.

FIG. 3 is a cross-sectional view illustrating a step for manufacturing the liquid crystal display device of the embodiment of the present invention.

FIG. 4 is a cross-sectional view illustrating a step for manufacturing the liquid crystal display device of the embodiment of the present invention.

FIG. 5 is a perspective view illustrating an electrodeposited grinding stone used at a step for manufacturing the liquid crystal display device of the embodiment of the present invention.

FIG. 6 is a cross-sectional view illustrating a step for manufacturing the liquid crystal display device of the embodiment of the present invention.

FIG. 7 is a cross-sectional view illustrating a step for manufacturing the liquid crystal display device of the embodiment of the present invention.

FIG. 8 is a cross-sectional view illustrating a step for manufacturing the liquid crystal display device of the embodiment of the present invention.

FIG. 9 is a view illustrating a strength measuring test in the embodiment.

FIG. 10 is a view illustrating the strength measuring test in the embodiment.

### DESCRIPTION OF EMBODIMENTS

An embodiment of the present invention will be described in detail below with reference to the drawings. Note that the present invention is not limited to the embodiment below.

(Configuration of Liquid Crystal Display Device 1)

FIG. 1 is a cross-sectional view of a liquid crystal display device of the embodiment of the present invention. As illustrated in FIG. 1, the liquid crystal display device 1 includes a liquid crystal display panel 14 and a backlight 15.

The liquid crystal display panel 14 includes a TFT substrate 11 which is a first substrate provided on a side from which display light from the backlight 15 enters, and a CF substrate 12 which is a second substrate facing the TFT substrate 11. In addition, the liquid crystal display panel 14 further includes a liquid crystal layer 13 which is a display medium layer provided between the TFT substrate 11 and the CF substrate 12, and sealing material 25 bonding the TFT substrate 11 and the CF substrate 12 together and provided in a frame-like shape to seal the liquid crystal layer 13. The sealing material 25 is formed so as to surround the liquid crystal layer 13, and the TFT substrate 11 and the CF substrate 12 are bonded together with the sealing material 25. The CF substrate 12 is provided on a side from which the display light exits, so as to face the TFT substrate 11 through the liquid crystal layer 13.

For the liquid crystal display device 1 of the present embodiment, an example of a bright spot defect caused by entering a foreign substance 16 into the liquid crystal layer 13 will be described. However, such a bright spot defect is not limited to the foregoing, and may be an alignment defect caused due to, e.g., irregular arrangement of an alignment film.

The TFT substrate 11 includes a glass substrate 21. The TFT substrate 11 further includes TFT elements each including a gate electrode, a source electrode, a drain electrode, etc., a transparent insulating layer, pixel electrodes, an alignment film, etc. which are formed on the glass substrate 21 and are not shown in the figure. A back polarizing plate 17 is arranged on an outer surface of the TFT substrate 11.

As the glass substrate 21, e.g., alkali-free glass which does not contain alkali metal such as sodium, aluminosilicate glass, aluminoborosilicate glass, etc. can be used. Since the liquid crystal display device 1 of the present embodiment is a liquid crystal display device including the medium-to-small size liquid crystal display panel 14, the glass substrate 21 having a thickness of 200 μm-700 μm can be used.

As illustrated in FIG. 1, a recessed portion 2 is formed in a region of the glass substrate 21 (i.e., in a position optically overlapped with a bright spot defective portion 18) corresponding to the bright spot defective portion 18 of the liquid crystal layer 13 (i.e., corresponding to a position of the foreign substance 16) on a surface of the glass substrate 21 of the TFT substrate 11, which is opposite to a surface facing the liquid crystal layer 13. In addition, a light-shielding portion 3 made of light-shielding material is formed in the recessed portion 2.

The light-shielding portion 3 covers the bright spot defective portion 18 when viewing the glass substrate 21 in a plan view so that incident light (display light) from the backlight 15 arranged in the back of the liquid crystal display panel 14 cannot reach the bright spot defective portion 18. The light-shielding portion 3 is formed in a cylindrical shape extending from an outer surface of the glass substrate 21 in a thickness direction of the liquid crystal display panel 14 (or the glass substrate 21). The light-shielding portion 3 is made of, e.g., black resin having a light-shielding property.

The shape of the light-shielding portion 3 is not limited to the foregoing, and any shapes may be employed as long as the light-shielding portion 3 covers the bright spot defective portion 18 of the liquid crystal layer 13. In addition, the light-shielding portion 3 is not necessarily formed in the outer surface of the glass substrate 21, and, e.g., may be formed so as to be completely embedded in the glass substrate 21.

The CF substrate 12 includes, e.g., a color filter (not shown in the figure) having a black matrix (not shown in the figure) provided in a grid pattern and provided in a frame-like shape as a light-shielding portion on a glass substrate 22 and colored layers such as red layers, green layers, and blue layers, each of which is provided between the grids of the black matrix. In addition, the CF substrate 12 further includes a common electrode (not shown in the figure) provided so as to cover the black matrix and the color filter, photo spacers (not shown in the figure) provided in a column-like shape on the common electrode, and an alignment film (not shown in the figure) provided so as to cover the common electrode. A front polarizing plate 19 is arranged on an outer surface of the CF substrate 12. Note that a glass substrate similar to that of the glass substrate 21 may be used as the glass substrate 22. The glass substrate 22 having a thickness of 100 μm-700 μm can be used.

The liquid crystal layer 13 is made of, e.g., nematic liquid crystal material having an electrooptical property.

The backlight 15 is arranged on a side closer to the TFT substrate 11 of the liquid crystal display panel 14. The backlight 15 includes a light source, a light guide plate through which, after light from the light source is received, the light is propagated and exits toward the liquid crystal display panel 14, and an reflector on which the light exiting through a back surface of the light guide plate is reflected toward the light guide plate (the foregoing components of the backlight 15 are not shown in the figure).

(Method for Manufacturing Liquid Crystal Display Device 1)

Next, a method for manufacturing the liquid crystal display device 1 of the present embodiment will be described with reference to the drawings.

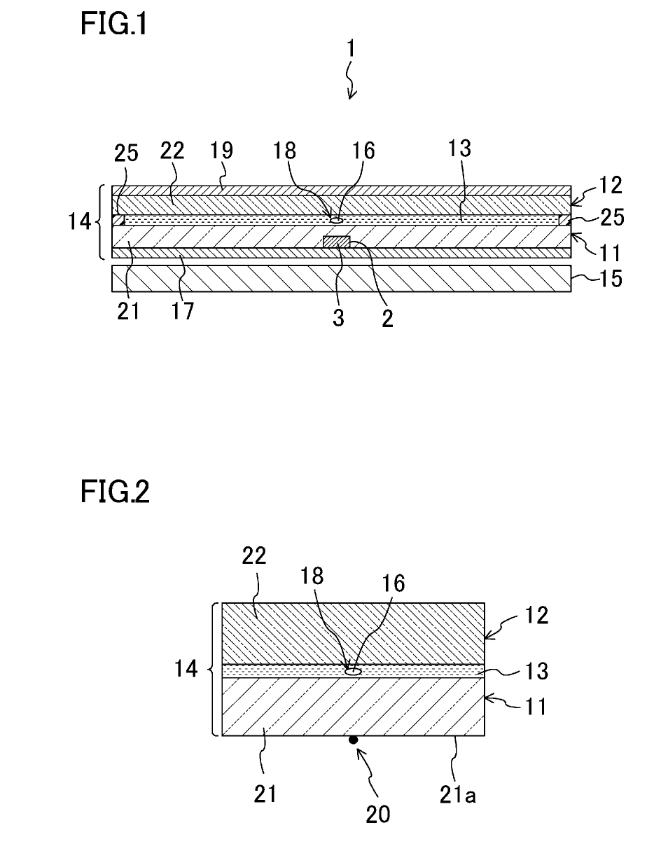

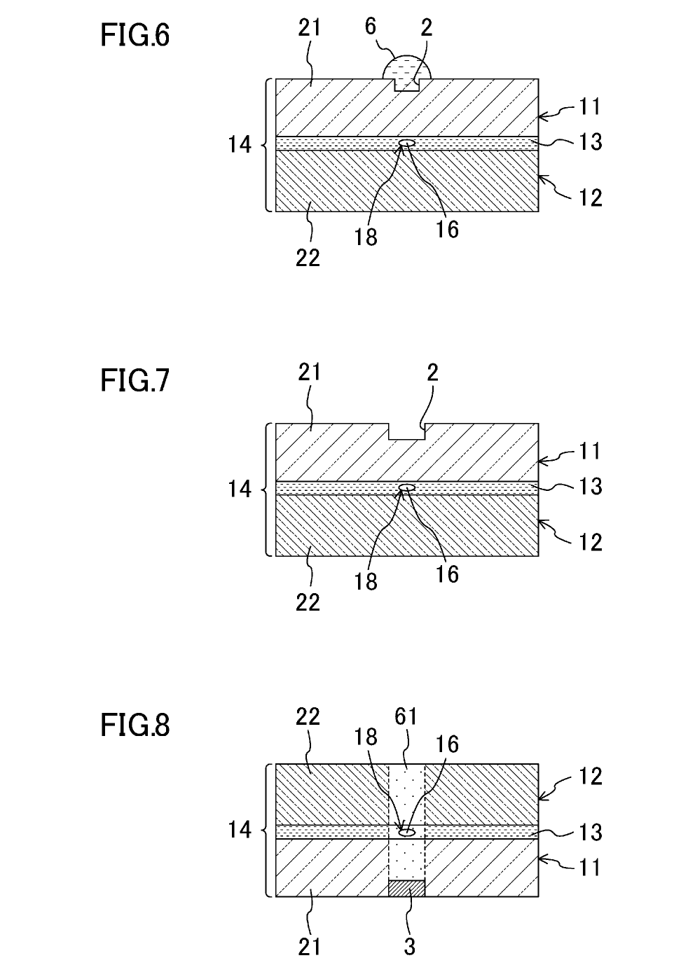

FIGS. 2-4 are cross-sectional views illustrating steps for manufacturing the liquid crystal display device of the embodiment of the present invention. FIG. 5 is a perspective view illustrating an electrodeposited grinding stone used at the steps for manufacturing the liquid crystal display device of the embodiment of the present invention. FIGS. 6-7 are cross-sectional views illustrating steps for manufacturing the liquid crystal display device of the embodiment of the present invention.

First, TFT elements, pixel electrodes, etc. are patterned on a glass substrate 21, and a TFT array layer forming a display region is formed. Then, polyimide resin is applied to the entire substrate by printing. Subsequently, rubbing is performed to form an alignment film, thereby producing a TFT substrate 11.

Meanwhile, a color filter including colored layers and a black matrix, a common electrode, etc. are patterned on a glass substrate 22, and a CF element layer forming a display region is formed. Then, polyimide resin is applied to the entire substrate by the printing. The rubbing is performed to form an alignment film, thereby producing a CF substrate 12. Subsequently, e.g., spherical particles of silica and plastic are sprayed to the entire substrate, thereby forming spacers.

Subsequently, a dispenser is used to draw sealing material 25 made of, e.g., combined resin of ultraviolet curable resin and thermal curable resin in a frame-like shape on the CF substrate 12.

Then, liquid crystal material is dropped to a region surrounded by the sealing material 25 on the CF substrate 12 to which the sealing material 25 is drawn.

Subsequently, the CF substrate 12 to which the liquid material is dropped and the TFT substrate 11 are bonded together under reduced pressure.

Then, the bonded body is released to atmospheric pressure, thereby pressurizing front and back surfaces of the bonded body. After the sealing material 25 sandwiched between the substrates of the bonded body is irradiated with UV light, the bonded body is heated, thereby curing the sealing material 25.

Subsequently, a back polarizing plate 17 is provided on an outer surface of the TFT substrate 11, and a front polarizing plate 19 is provided on an outer surface of the CF substrate 12.

In the foregoing manner, a liquid crystal display panel 14 is manufactured.

Subsequently, a lighting test is performed for the liquid crystal display panel 14, and it is checked whether or not light from the backlight 15 is leaked. More specifically, e.g., test signals are input to all of the pixel electrodes of the TFT substrate 11 and the common electrode of the CF substrate 12, and all of the pixels are in a light-on state. In addition, the liquid crystal display panel 14 is irradiated with light from the backlight 15 from the back of the liquid crystal display panel 14 (i.e., from a side closer to TFT substrate 11). If there is a pixel in which a short circuit is caused due to a foreign substance 16 interposed between the pixel electrode and the common electrode, the light from the backlight 15 is leaked from such a defective pixel, and the defective pixel is detected as a bright spot.

Subsequently, as illustrated in FIG. 2, a mark 20 is placed in a region on the outer surface of the TFT substrate 11 (i.e., a surface 21a of the glass substrate 21), which corresponds to a position where the light leakage is caused. A polarizing plate etc. are used to specify a bright spot defective portion 18 corresponding to the mark 20.

Subsequently, as illustrated in FIG. 4, in a region of the glass substrate 21 (i.e., in a position optically overlapped with the bright spot defective portion 18) corresponding to the bright spot defective portion 18 of a liquid crystal layer 13 (i.e., corresponding to the foreign substance 16) on a surface of the glass substrate 21 of the TFT substrate 11, which is opposite to a surface facing the liquid crystal layer 13, a recessed portion 2 is formed in a position covering the bright spot defective portion 18 so that incident light from the backlight 15 does not reach the bright spot defective portion 18.

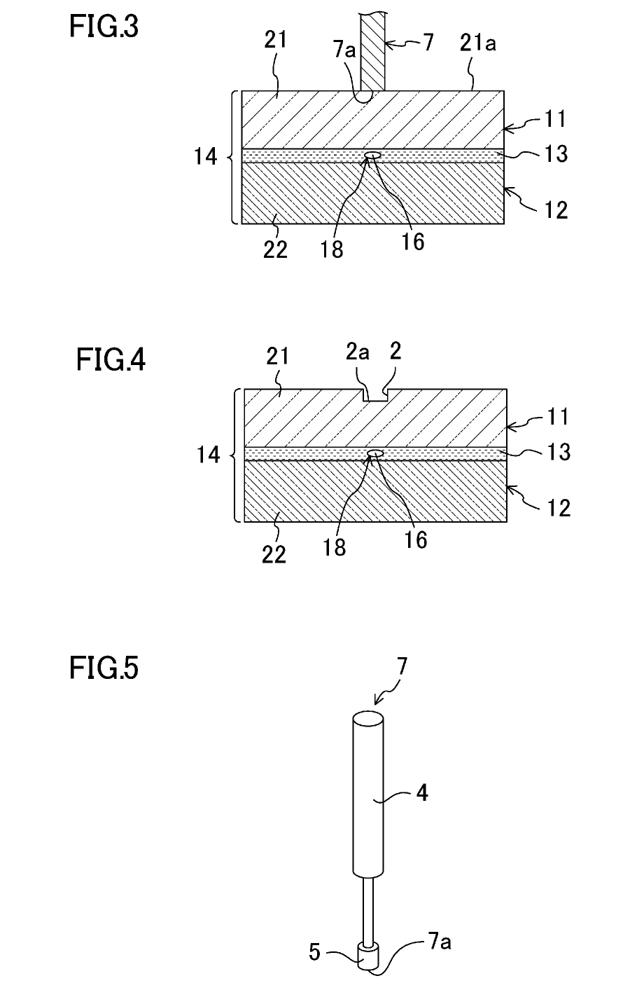

The present embodiment is characterized in that the recessed portion 2 is formed in the glass substrate 21 by grinding the glass substrate 21 with the electrodeposited grinding stone. More specifically, as illustrated in FIG. 3, the recessed portion 2 is formed by grinding the glass substrate 21 while an electrodeposited grinding stone 7 rotates and presses against the surface 21a of the glass substrate 21.

As described above, the cutting with the carbide drill is performed to form a recessed portion having a depth of about 200 μm-300 μm. Thus, when the recessed portion is formed by cutting a glass substrate having only a thickness of about 200 μm with the carbide drill, the remaining portion of the glass substrate in the recessed portion cannot be ensured or becomes extremely thin. Thus, there is a problem that strength of the glass substrate is significantly reduced, and the glass substrate is easily broken even when small force is applied to the recessed portion.

On the other hand, the grinding with the electrodeposited grinding stone 7 allows formation of the recessed portion 2 having a depth of about 50-100 μm. Thus, even when the recessed portion 2 is formed by grinding the glass substrate 21 having only a thickness of about 200 μm with the electrodeposited grinding stone 7, the sufficient remaining portion of the glass substrate 21 in the recessed portion 2 can be ensured. Consequently, sufficient strength of the glass substrate 21 can be ensured even when the recessed portion 2 is formed.

There is a typical problem that, when cutting a glass substrate with a carbide drill, chipping (chips) is caused with microcracks in many portions of the glass substrate at a rim of a recessed portion, and therefore strength of the glass substrate is significantly reduced.

On the other hand, the grinding with the electrodeposited grinding stone 7 is not cutting by peeling off (scrabbling) glass with a chisel portion such as a tip end of the carbide drill. Thus, unlike the cutting with the carbide drill, occurrence of the chipping can be effectively reduced. Consequently, even if the recessed portion 2 is formed in the thin glass substrate 21 having only the thickness of about 200 μm, the sufficient strength of the glass substrate 21 can be ensured.

As illustrated in FIG. 5, e.g., an electrodeposited grinding stone including a cylindrical base 4 and a grinding stone portion 5 formed by solidifying abrasive grains such as diamond abrasive grains with nickel plate etc. can be used as the electrodeposited grinding stone 7. A method for manufacturing the electrodeposited grinding stone 7 is as follows. First, a base 4 and electrolytic metal are soaked in an electrolytic solution. Next, voltage is applied between the base 4 and the electrolytic metal. Then, abrasive grains mixed with the electrolytic solution are precipitated and accumulated on the base 4. Subsequently, the accumulated abrasive grains are electrodeposited and solidified with the dissolved electrolytic metal, thereby forming a grinding stone portion 5.

As illustrated in FIGS. 3 and 5, it is preferred that a tip end 7a of the electrodeposited grinding stone 7 (i.e., a portion of the electrodeposited grinding stone 7, which is to contact the glass substrate 21) is flattened in shape. Since such an electrodeposited grinding stone 7 is used to flatten a bottom surface 2a of the recessed portion 2 as illustrated in FIG. 4, black resin which is light-shielding material supplied to the recessed portion 2 can be effectively held.

The present embodiment is characterized in that, after the recessed portion 2 is formed in the glass substrate 21 with the electrodeposited grinding stone 7, etching is performed for the recessed portion 2.

As described above, although the grinding with the electrodeposited grinding stone 7 is performed to effectively reduce the occurrence of the chipping, there is a possibility that a few microcracks are caused in the recessed portion 2 formed with the electrodeposited grinding stone 7. However, in the present embodiment, even if the microcracks are caused in the recessed portion 2 due to the grinding with the electrodeposited grinding stone 7, the microcracks can be sealed by etching the recessed portion 2. This allows improvement of the strength of the glass substrate 21 including the recessed portion 2. As a result, in the liquid crystal display device 1 including the medium-to-small size liquid crystal display panel 14 from which the defective pixel is detected as the bright spot, the bright spot defect can be corrected. Thus, the liquid crystal display device 1 including the medium-to-small size liquid crystal display panel 14 from which the defective pixel is detected as the bright spot can be repaired without being disposed. Consequently, a manufacturing yield rate of the liquid crystal display device 1 can be improved.

It is preferred that hydrofluoric acid which is a water solution of hydrogen fluoride is used as an etching solution to be used. By using the hydrofluoric acid, the microcracks can be effectively sealed by a hardening effect due to erosion of hydrofluoric acid. As a result, the strength of the glass substrate 21 including the recessed portion 2 can be further improved, thereby further improving the manufacturing yield rate of the liquid crystal display device 1.

It is preferred that a water solution containing hydrogen fluoride of 20-30% by mass (i.e., a concentration of hydrofluoric acid is 20-30% by mass) is used as the hydrofluoric acid to be used. This is because the microcracks cannot be sufficiently sealed if the concentration of hydrogen fluoride is less than 20% by mass, and a disadvantage called “over-etching” is caused if the concentration of hydrogen fluoride is greater than 30% by mass.

As illustrated in FIG. 6, when performing the etching, the recessed portion 2 formed by grinding the glass substrate 21 with the electrodeposited grinding stone 7 is first filled with hydrofluoric acid 6, and then the etching is performed at a predetermined etching rate for a predetermined period of time. Subsequently, the etched recessed portion 2 is washed with water, thereby forming the etched recessed portion 2 as illustrated in FIG. 7.

It is assumed that the length (or the depth) of the microcrack caused due to the grinding with the electrodeposited grinding stone 7 is about 0.5 μm. Thus, in view of ensuring the sealing of the microcracks caused in the recessed portion 2 by the hardening effect due to erosion of hydrofluoric acid, it is preferred that, if the hydrofluoric acid of 20-30% by mass is used, the etching rate is set to 2-10 μm/minute. In such a case, in view of further ensuring the sealing of the microcracks by the hardening effect due to erosion of hydrofluoric acid, it is preferred that an etching time is set to 20-90 seconds.

Next, black resin which is the light-shielding material is supplied to the recessed portion 2, and then is cured by e.g., heating the black resin or leaving the black resin at room temperature, thereby forming the light-shielding portion 3 in the recessed portion 2 as illustrated in FIG. 8. When display light from the backlight 15 enters the TFT substrate 11 including the light-shielding portion 3 from the back thereof, the incident light is shielded, and a light-shielded region 61 is appeared in the liquid crystal display panel 14 as illustrated in FIG. 8. Thus, the bright spot defect can be corrected.

Note that e.g., lacquer synthetic resin coating can be used as the black resin forming the light-shielding material. Since the lacquer synthetic resin coating is lustrous and has a high resin content, such coating looks rounded. In addition, drying of the lacquer synthetic resin coating is oxidative polymerization in which oxygen in air is taken, and the lacquer synthetic resin coating can be naturally dried. Thus, the lacquer synthetic resin coating can be suitably used as the light-shielding material of the present embodiment.

According to the present embodiment described above, the following advantages can be obtained.

In the present embodiment, the configuration is employed, in which the electrodeposited grinding stone 7 grinds the region of the glass substrate 21 corresponding to the bright spot defective portion 18 on the surface of the glass substrate 21, which is opposite to the surface facing the liquid crystal layer 13, thereby forming the recessed portion 2. Thus, unlike the cutting with the carbide drill, the recessed portion 2 having the depth of about 50-100 μm can be formed, and the occurrence of the chipping at the rim of the recessed portion 2 can be effectively reduced. As a result, even if the recessed portion 2 is formed in the thin glass substrate 21, the sufficient strength of the glass substrate 21 can be ensured. In addition, the configuration is employed, in which the recessed portion 2 is etched. Thus, even if the microcracks are caused in the recessed portion 2 due to the grinding with the electrodeposited grinding stone 7, the microcracks can be sealed. Consequently, the strength of the glass substrate 21 including the recessed portion 2 can be improved.

As a result, in the liquid crystal display device 1 including the medium-to-small size liquid crystal display panel 14 from which the defective pixel is detected as the bright spot, the bright spot defect can be corrected. Thus, the liquid crystal display device 1 including the medium-to-small size liquid crystal display panel 14 from which the defective pixel is detected as the bright spot can be repaired without being disposed, and the manufacturing yield rate of the liquid crystal display device 1 can be improved.

In the present embodiment, the configuration is employed, in which the etching is performed by using hydrofluoric acid. Thus, the microcracks can be effectively sealed by the hardening effect due to erosion of hydrofluoric acid in the recessed portion 2 formed in the glass substrate 21. As a result, the strength of the glass substrate 21 including the recessed portion 2 can be further improved, thereby further improving the manufacturing yield rate of the liquid crystal display device 1.

In the present embodiment, when the etching is performed, the concentration of hydrofluoric acid is 20-30% by mass, and the etching rate is 2-10 μm/minute. Thus, the sealing of the microcracks caused in the recessed portion 2 can be ensured by the hardening effect due to erosion of hydrofluoric acid.

In the present embodiment, the configuration is employed, in which, when the etching is performed, the etching time is set to 20-90 seconds. Thus, the sealing of the microcracks caused in the recessed portion 2 can be further ensured by the hardening effect due to erosion of hydrofluoric acid.

In the present embodiment, the configuration is employed, in which the electrodeposited grinding stone 7 having the flat tip end 7a is used. Thus, since the bottom surface 2a of the recessed portion 2 is flattened, the light-shielding material supplied to the recessed portion 2 can be effectively held when the light-shielding portion 3 is formed.

Note that the foregoing embodiment may be changed as follows.

In the foregoing embodiment, the liquid crystal display device 1 including the medium-to-small size liquid crystal display panel 14 from which the defective pixel is detected as the bright spot has been described as an example. However, needless to say, the present invention may be applied to a liquid crystal display device including a large size liquid crystal display panel from which a defective pixel is detected as a bright spot. According to such a configuration, the liquid crystal display device including the large size liquid crystal display panel can be repaired without being disposed, thereby improving the manufacturing yield rate of the liquid crystal display device.

In the foregoing embodiment, the configuration is employed, in which the recessed portion 2 is formed in the glass substrate 21 of the TFT substrate 11, and the light-shielding portion 3 is formed in the recessed portion 2. However, as in the case of the foregoing embodiment, the recessed portion 2 may be formed in the glass substrate 22 of the CF substrate 12, and the light-shielding portion 3 may be formed in the recessed portion 2. More specifically, the electrodeposited grinding stone 7 first grinds a region of the glass substrate 22 corresponding to the bright spot defective portion 18 on a surface of the glass substrate 22 of the CF substrate 12, which is opposite to a surface facing the liquid crystal layer 13, thereby forming a recessed portion 2. Next, the recessed portion 2 is etched, and the light-shielding portion 3 made of the light-shielding material is formed in the recessed portion 2. In such a configuration, advantages similar to those of the foregoing embodiment can be obtained.

### EXAMPLE

An evaluation test for checking strength of a liquid crystal display panel has been conducted.

(Production of Liquid Crystal Display Panel for Evaluation)

First, a liquid crystal display panel was prepared, from which a bright spot defect was detected. More specifically, a liquid crystal display panel has been prepared, which includes a TFT substrate which has a glass substrate made of alkali-free glass and having a thickness of 225 μm, a CF substrate which has a glass substrate made of alkali-free glass and having a thickness of 225 μm, and a liquid crystal layer having a thickness of 3 μm.

Next, the electrodeposited grinding stone illustrated in FIG. 5 was used to grind the glass substrate of the TFT substrate, thereby forming a recessed portion having a diameter of 100 μm and a depth of 100 μm.

Subsequently, hydrofluoric acid of 20-30% by mass was used to etch the recessed portion formed by grinding the glass substrate. Note that the etching was performed at an etching rate of 6 μmm/minute for etching times of 60 and 120 seconds.

(Strength Measuring Test)

Next, by a strength measuring test according to a metallic material tensile testing method, strength of the liquid crystal display panel which has been etched for 60 seconds (hereinafter referred to as “strength after the lapse of 60 seconds”) and strength of the liquid crystal display panel which has been etched for 120 seconds (hereinafter referred to as “strength after the lapse of 120 seconds”) were measured.

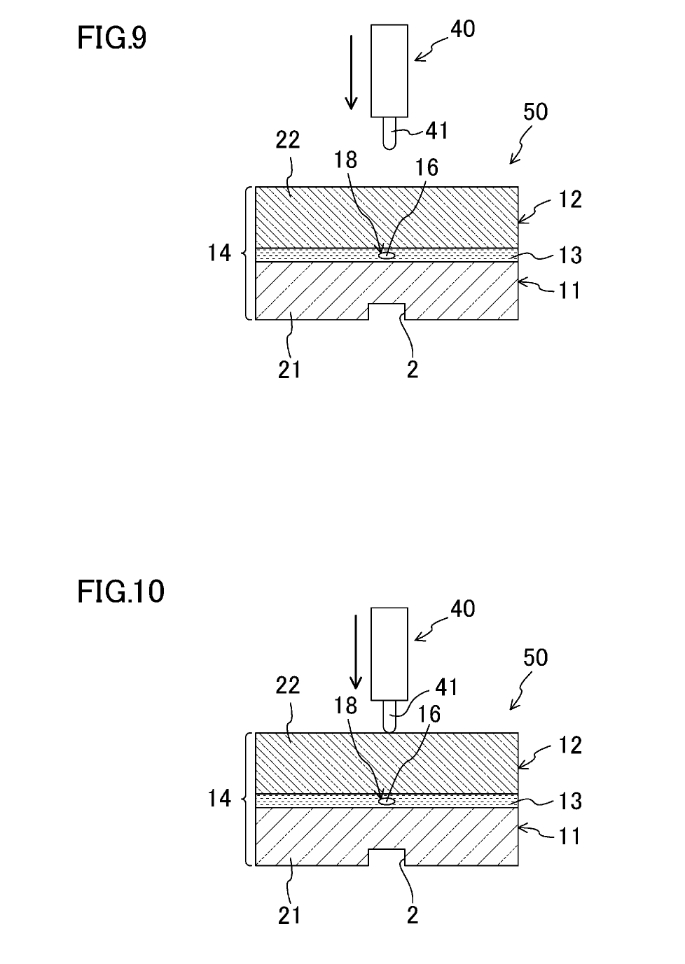

More specifically, a strength measuring device (manufactured by INSTRON under the product name of INSTRON 5543) was used. First, as illustrated in FIG. 9, a pressing member 41 of the strength measuring device 40 was arranged on a side closer to a glass substrate 22 of a CF substrate 12 of a liquid crystal display panel 50, i.e., on a side closer to a liquid crystal layer 13 relative to a glass substrate 21 of a TFT substrate 11, in which a recessed portion 2 is formed. Next, the pressing member 41 was moved toward the CF substrate 12 (i.e., in a direction indicated by an arrow in FIG. 9) at a speed of 0.5 mm/minute. As illustrated in FIG. 10, the pressing member 41 contacted a region of a surface of the CF substrate 12 corresponding to a position of the recessed portion 2 of the TFT substrate 11, followed by pressing against the liquid crystal display panel 50. In such a manner, a load (a unit thereof is “kgf”) when the glass substrate 21 of the TFT substrate 11, which includes the recessed portion 2 was broken was measured as the strength of the liquid crystal display panel 50. In addition, in the similar manner, the strength of the liquid crystal display panel before etching (i.e., right after the recessed portion was formed) (hereinafter referred to as “pre-etching strength”) was also measured. The results thereof are shown in Table 1.

TABLE 1

| | Load (kgf) |
|---|---|
| Pre-etching strength | 2.7 |
| Strength after the lapse of 60 seconds | 3.1 |
| Strength after the lapse of 120 seconds | 10.1 |

As will be seen from Table 1, the strength after the lapse of 60 seconds (3.1 kgf) and the strength after the lapse of 120 seconds (10.1 kgf) were improved as compared to the pre-etching strength (2.7 kgf). In particular, the strength after the lapse of 120 seconds has been dramatically improved as compared to the pre-etching strength. It is assumed that such improvement was achieved because microcracks caused in the recessed portion 2 due to the grinding with the electrodeposited grinding stone 7 are sealed by the etching. When the etching has been performed for 120 seconds, the etching was sufficiently performed in the recessed portion 2. Thus, it is assumed that the sealing of the microcracks caused in the recessed portion 2 was ensured by the etching.

### INDUSTRIAL APPLICABILITY

An application example of the present invention includes the method for manufacturing the liquid crystal display device in which the pair of substrates are stacked with the predetermined clearance being interposed therebetween and the liquid crystal layer is sealed in the clearance between the pair of substrates, and the liquid crystal display device manufactured by the method.

### DESCRIPTION OF REFERENCE CHARACTERS

1 Liquid Crystal Display Device
2 Recessed Portion
3 Light-Shielding Portion
6 Hydrofluoric Acid
7 Electrodeposited Grinding Stone
7a Tip End of Electrodeposited Grinding Stone
11 TFT Substrate (First Substrate)
12 CF Substrate (Second Substrate)
13 Liquid Crystal Layer
14 Liquid Crystal Display Panel
16 Foreign Substance
18 Bright Spot Defective Portion
21 Glass Substrate

1. A method for manufacturing a liquid crystal display device, comprising at least:
preparing a liquid crystal display panel which includes a first substrate having a glass substrate and a second substrate provided so as to face the first substrate with a liquid crystal layer being interposed therebetween and which has a bright spot defective portion therein;
forming a recessed portion by grinding a region of the glass substrate corresponding to the bright spot defective portion on a surface of the glass substrate, which is opposite to a surface facing the liquid crystal layer, with an electrodeposited grinding stone;
etching the recessed portion; and
forming a light-shielding portion made of light-shielding material in the recessed portion.

2. The method of claim 1, wherein,
in the etching the recessed portion, hydrofluoric acid is used to perform the etching.

3. The method of claim 2, wherein,
in the etching the recessed portion, a concentration of the hydrofluoric acid is 20-30% by mass, and an etching rate is 2-10 μm/minute.

4. The method of claim 3, wherein,
in the etching the recessed portion, an etching time is 20-90 seconds.

5. The method of claim 1, wherein
a thickness of the glass substrate is 200-700 μm.

6. The method of claim 5, wherein
the glass substrate is made of a material selected from a group including alkali-free glass, aluminosilicate glass, and aluminoborosilicate glass.

7. The method of claim 1, wherein
in the forming a recessed portion, a portion of the electrodeposited grinding stone, which is to contact the glass substrate is flattened in shape.

8. A liquid crystal display device manufactured by the method of claim 1.

9. The method of claim 2, wherein
a thickness of the glass substrate is 200-700 μm.

10. The method of claim 3, wherein
a thickness of the glass substrate is 200-700 μm.

11. The method of claim 4, wherein
a thickness of the glass substrate is 200-700 μm.

12. The method of claim 2, wherein
in the forming a recessed portion, a portion of the electrodeposited grinding stone, which is to contact the glass substrate is flattened in shape.

13. The method of claim 3, wherein
in the forming a recessed portion, a portion of the electrodeposited grinding stone, which is to contact the glass substrate is flattened in shape.

14. The method of claim 4, wherein
in the forming a recessed portion, a portion of the electrodeposited grinding stone, which is to contact the glass substrate is flattened in shape.

15. The method of claim 5, wherein
in the forming a recessed portion, a portion of the electrodeposited grinding stone, which is to contact the glass substrate is flattened in shape.

16. The method of claim 6, wherein
in the forming a recessed portion, a portion of the electrodeposited grinding stone, which is to contact the glass substrate is flattened in shape.

17. A liquid crystal display device manufactured by the method of claim 2.

18. A liquid crystal display device manufactured by the method of claim 3.

19. A liquid crystal display device manufactured by the method of claim 4.

20. A liquid crystal display device manufactured by the method of claim 5.
